(19) United States
(12) Patent Application Publication
(10) Pub. No.: US 2011/0220170 A1
(43) Pub. Date: Sep. 15, 2011

(54) DYE-SENSITIZED SOLAR CELL

(75) Inventors: Naohiro OBONAI, Tokyo-to (JP); Miho SASAKI, Tokyo-to (JP)

(73) Assignee: DAI NIPPON PRINTING CO., LTD., Tokyo-to (JP)

(21) Appl. No.: 13/039,503

(22) Filed: Mar. 3, 2011

(30) Foreign Application Priority Data
Mar. 11, 2010 (JP) 2010-055032

(51) Int. Cl. H01L 31/042; H01L 31/0224; B32B 15/00; B32B 15/20; B32B 7/00

(52) U.S. Cl. 136/244; 136/256; 428/655; 428/651; 428/609

(57) ABSTRACT

An object of the present invention is to provide a conductive base material for dye-sensitized solar cell and a transparent conductive base material for dye-sensitized solar cell which, when used as electrode base materials of a dye-sensitized solar cell, have high resistance to corrosion by iodide ions contained in an electrolyte layer and can prevent a reduction in the fill factor and conversion efficiency of the dye-sensitized solar cell to achieve high power generation efficiency, a dye-sensitized solar cell and a dye-sensitized solar cell module using such conductive base materials. To attain the object, provided is the conductive base material for dye-sensitized solar cell comprising: a first metal layer made of a metal having a specific resistance of 6×10⁻⁶ Ω·m or less; and a second metal layer formed on the first metal layer, made of any one of metals of Ti, Cr, Ni, Mo, Ta, W, Nb, and Pt, and having a thickness of 500 nm or less.

### BACKGROUND OF THE INVENTION

1. Field of the Invention

The present invention relates to a conductive base material for dye-sensitized solar cell, a transparent conductive base material for dye-sensitized solar cell, a dye-sensitized solar cell, and a dye-sensitized solar cell module.

2. Description of the Related Art

In recent years, environmental issues such as global warming believed to be caused by an increase in CO₂ have become serious, and therefore measures have been taken to deal with such environmental issues on a worldwide basis. Particularly, research and development of solar cells utilizing the energy of sunlight has been actively conducted as clean energy sources that have a low impact on the environment. As such solar cells, monocrystal silicon solar cells, polycrystal silicon solar cells, amorphous silicon solar cells, and compound semiconductor solar cells, and the like have already been put to practical use. However, these solar cells have problems such as high production cost, etc. For this reason, dye-sensitized solar cells have received attention as environmentally-friendly solar cells that can be produced at lower cost, and research and development of such dye-sensitized solar cells has been conducted.

FIG. 9 shows one example of a general structure of a dye-sensitized solar cell. As shown in FIG. 9, a general dye-sensitized solar cell 100 comprises: an oxide semiconductor electrode substrate 110 that has a first electrode base material 111 functioning as an electrode and a porous layer 112 formed on the first electrode base material 111 and containing dye-sensitizer-supported fine particles of a metal oxide semiconductor; a counter electrode substrate 120 that has a second electrode base material 121 functioning as an electrode and a catalyst layer 122 formed on the second electrode base material 121; and an electrolyte layer 103 that contains a redox pair and is provided between the oxide semiconductor electrode substrate 110 and the counter electrode substrate 120 arranged so that the porous layer 112 and the catalyst layer 122 are opposed to each other. The ends of the dye-sensitized solar cell 100 are sealed with a sealing agent 104. When the dye-sensitized solar cell 100 receives solar light from the first electrode base material 111 side, the dye sensitizer adsorbed to the surface of the metal oxide semiconductor fine particles contained in the porous layer 112 is excited, and then excited electrons are transferred to the first electrode base material 111 and are then transferred to the second electrode base material 121 through an external circuit. Then, the electrons are returned to the ground state of the dye sensitizer by the redox pair so that electricity is generated. It is to be noted that the dye-sensitized solar cell shown in FIG. 9 uses, as the first electrode base material 111 and the second electrode base material 121, an electrode base material having a transparent first base material 111b and a transparent electrode layer 111a formed on the first base material 111b, and an electrode base material having a transparent second base material 121b and a transparent electrode layer 121a formed on the second base material 121b, respectively; but the dye-sensitized solar cell generally receives solar light from one of the first electrode base material side and the second electrode base material side, and therefore only one of the electrode base materials may be a base material having transparency.

Further, in recent years, there has been a growing demand for an increase in the area of such a dye-sensitized solar cell as described above. Therefore, an attempt to achieve a large-area device having high electricity extraction efficiency has been made by using a metal base material as an electrode layer constituting the first electrode base material or the second electrode base material. However, the electrolyte layer of the dye-sensitized solar cell uses an electrolyte containing iodide ions, and therefore the electrode layer needs to be composed of a metal base material that stably exhibits high resistance to corrosion by iodide ions over long periods of time. An example of such a metal base material includes a titanium base material. However, a dye-sensitized solar cell using a titanium base material as an electrode layer has a problem of high production cost.

In order to solve such a problem, there has been a demand for a cheap metal base material that can be used as the electrode layer instead of a titanium base material, but many metal base materials are inferior in resistance to corrosion by iodide ions to a titanium base material.

In order to improve the resistance to corrosion by iodide ions of an electrode layer used in a dye-sensitized solar cell, for example, Japanese Patent Application Laid-Open (JP-A) No. 2007-87744 discloses an electrode layer composed of a cladding material formed from an aluminum plate and a nickel plate.

However, the electrode layer disclosed in JP-A No. 2007-87744 uses a nickel plate having a thickness of 1 mm, and therefore there is a problem that electrical resistance caused by the nickel plate is high, which reduces the fill factor and power generation efficiency of a dye-sensitized solar cell. Further, there is also a problem that the amount of material and time required to form a nickel plate having a thickness of 1 mm is high, and therefore production cost is high even when a highly-productive method such as a gas-phase plating method, a liquid-phase plating method, a printing method, or a coating method is used. Further, even when a nickel plate having a thickness of 1 mm is formed by a gas-phase plating method, a liquid-phase plating method, a printing method, or a coating method, cracks are formed in the nickel plate and then iodide ions penetrate the cracks, which makes it difficult to allow the electrode layer to have satisfactory resistance to corrosion by iodide ions.
Patent Document: Japanese Patent Application Laid-Open (JP-A) No. 2007-87744

### SUMMARY OF THE INVENTION

It is therefore a main object of the present invention to provide a conductive base material for dye-sensitized solar cell and a transparent conductive base material for dye-sensitized solar cell which, when used as electrode base materials of a dye-sensitized solar cell, have high resistance to corrosion by iodide ions contained in an electrolyte layer and can prevent a reduction in the conversion efficiency of the dye-sensitized solar cell to achieve high power generation efficiency, a dye-sensitized solar cell using such conductive base materials, and a dye-sensitized solar cell module using such dye-sensitized solar cells.

To solve the problems, the present invention provides a conductive base material for dye-sensitized solar cell comprising: a first metal layer made of a metal having a specific resistance of 6×10⁻⁶ Ω·m or less; and a second metal layer formed on the first metal layer, made of any one of metals of Ti, Cr, Ni, Mo, Ta, W, Nb, and Pt, and having a thickness of 500 nm or less.

According to the present invention, the conductive base material for dye-sensitized solar cell has the second metal layer. Therefore, when the conductive base material for dye-sensitized solar cell according to the present invention is used as an electrode layer of a dye-sensitized solar cell, the electrode layer can have high resistance to corrosion by iodide ions contained in an electrolyte layer.

Further, when the conductive base material for dye-sensitized solar cell according to the present invention is used as an electrode layer of a dye-sensitized solar cell, electrical resistance caused by the second metal layer is low because the second metal layer is formed as a thin film on the first metal layer. Further, according to the present invention, the first metal layer is made of a metal having a low specific resistance, and therefore the electrical resistance of the electrode layer can be made low as a whole, which makes it possible to prevent a reduction in the fill factor of the dye-sensitized solar cell. Therefore, the use of the conductive base material for dye-sensitized solar cell according to the present invention makes it possible to provide a dye-sensitized solar cell having high conversion efficiency.

The present invention also provides a transparent conductive material for dye-sensitized solar cell comprising: a transparent base material; a transparent electrode layer formed on the transparent base material; and an auxiliary metal layer that has a mesh metal layer formed in a mesh on the transparent electrode layer and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less.

According to the present invention, the auxiliary metal layer has the second metal layer and therefore can have high resistance to corrosion by iodide ions, which allows the transparent conductive base material for dye-sensitized solar cell according to the present invention to have high resistance to corrosion by iodide ions as a whole. This makes it possible to provide an electrode base material having transparency and high resistance to corrosion by iodide ions. Further, the transparent conductive base material for dye-sensitized solar cell according to the present invention comprises the auxiliary metal layer, and therefore the use of the transparent conductive base material for dye-sensitized solar cell according to the present invention makes it possible to provide a dye-sensitized solar cell having high power generation efficiency.

The present invention provides a dye-sensitized solar cell, comprising: an oxide semiconductor electrode substrate that has: a first electrode base material functioning as an electrode, and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, wherein one of the first electrode base material and the second electrode base material has, as an electrode layer, a conductive base material for dye-sensitized solar cell that comprises a first metal layer made of a metal having a specific resistance of 6×10⁻⁶ Ω·m or less and a second metal layer formed on the first metal layer, made of any one of metals of Ti, Cr, Ni, Mo, Ta, W, Nb, and Pt, and having a thickness of 500 nm or less; and another is a base material having transparency.

According to the present invention, one of the first electrode base material and the second electrode base material has, as an electrode layer, the conductive base material for dye-sensitized solar cell. Therefore, the dye-sensitized solar cell according to the present invention can be of high quality, can have high resistance to corrosion by iodide ions contained in the electrolyte layer and high power generation efficiency, and can be less likely to be degraded with time. Further, the dye-sensitized solar cell according to the present invention can prevent a reduction in fill factor, which also allows the dye-sensitized solar cell according to the present invention to have high power generation efficiency.

According to the present invention, it is preferred that the first electrode base material has the conductive base material for dye-sensitized solar cell as the electrode layer and the second electrode base material is the base material having transparency. This is because electrons are more likely to move between the first metal layer and the porous layer through the second metal layer, which further enhance the power generation efficiency of the dye-sensitized solar cell according to the present invention.

The present invention provides a dye-sensitized solar cell comprising: an oxide semiconductor electrode substrate that has: a first electrode base material functioning as an electrode and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, wherein at least one of the first electrode base material and the second electrode base material is a transparent conductive base material for dye-sensitized solar cell that comprises a transparent base material, a transparent electrode layer formed on the transparent base material, and an auxiliary metal layer that has a mesh metal layer formed in a mesh on the transparent electrode layer and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less.

According to the present invention, at least one of the first electrode base material and the second electrode base material is the transparent conductive base material for dye-sensitized solar cell. Therefore, the dye-sensitized solar cell according to the present invention can be of high quality, can have high resistance to corrosion by iodide ions contained in the electrolyte layer and high power generation efficiency, and can be less likely to be degraded with time. Further, the dye-sensitized solar cell according to the present invention can prevent a reduction in fill factor, which also allows the dye-sensitized solar cell according to the present invention to have high power generation efficiency.

According to the present invention, it is preferred that the first electrode base material is the transparent conductive base material for dye-sensitized solar cell. This allows electrons to be more likely to move between the mesh metal layer and the porous layer through the second metal layer, which further enhance the power generation efficiency of the dye-sensitized solar cell according to the present invention.

The present invention provides a dye-sensitized solar cell module comprising two or more interconnected dye-sensitized solar cells, wherein each of the dye-sensitized solar cells comprises: an oxide semiconductor electrode substrate that has a first electrode base material functioning as an electrode and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, and wherein one of the first electrode base material and the second electrode base material has, as an electrode layer, a conductive base material for dye-sensitized solar cell that comprises a first metal layer made of a metal having a specific resistance of 6×10⁻⁶ Ω·m or less and a second metal layer formed on the first metal layer, made of any one of metals of Ti, Cr, Ni, Mo, Ta, W, Nb, and Pt, and having a thickness of 500 nm or less; and another is a base material having transparency.

The dye-sensitized solar cell module according to the present invention comprises the dye-sensitized solar cells described above, and therefore can have high power generation efficiency.

The present invention provides a dye-sensitized solar cell module comprising two or more interconnected dye-sensitized solar cells, wherein each of the dye-sensitized solar cells comprises: an oxide semiconductor electrode substrate that has a first electrode base material functioning as an electrode and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, and wherein at least one of the first electrode base material and the second electrode base material is a transparent conductive base material for dye-sensitized solar cell that comprises a transparent base material, a transparent electrode layer formed on the transparent base material, and an auxiliary metal layer that has a mesh metal layer formed in a mesh on the transparent electrode layer and made of a metal having a specific resistance of 6×10⁻⁶ Ω·m or less and a second metal layer formed on the mesh metal layer, made of any one of metals of Ti, Cr, Ni, Mo, Ta, W, Nb, and Pt, and having a thickness of 500 nm or less.

The dye-sensitized solar cell module according to the present invention comprises the dye-sensitized solar cells described above, and therefore can have high power generation efficiency.

### EFFECTS OF THE INVENTION

The present invention provides the conductive base material for dye-sensitized solar cell comprising a first metal layer and a second metal layer, which makes it possible to provide a dye-sensitized solar cell that has high resistance to corrosion by iodide ions contained in an electrolyte layer thereof and is less likely to be degraded with time. Further, the conductive base material for dye-sensitized solar cell has a low electrical resistance, and therefore the use of such a conductive base material for dye-sensitized solar cell in a dye-sensitized solar cell makes it possible to prevent a reduction in the fill factor of the dye-sensitized solar cell and therefore to allow the dye-sensitized solar cell to have high power generation efficiency.

### BRIEF DESCRIPTION OF THE DRAWINGS

FIG. 1 is a schematic sectional view of one example of a conductive base material for dye-sensitized solar cell according to the present invention;

FIG. 2 is a schematic sectional view of one example of a transparent conductive base material for dye-sensitized solar cell according to the present invention;

FIG. 3 is a schematic sectional view of one example of a dye-sensitized solar cell according to the present invention;

FIG. 4 is a schematic sectional view of another example of the dye-sensitized solar cell according to the present invention;

FIG. 5 is a schematic sectional view of another example of the dye-sensitized solar cell according to the present invention;

FIG. 6 is a schematic sectional view of another example of the dye-sensitized solar cell according to the present invention;

FIG. 7 is a schematic sectional view of one example of a dye-sensitized solar cell module according to the present invention;

FIG. 8 is a schematic sectional view of another example of the dye-sensitized solar cell module according to the present invention; and

FIG. 9 is a schematic sectional view of one example of a general dye-sensitized solar cell.

### DESCRIPTION OF THE PREFERRED EMBODIMENT

Hereinbelow, a conductive base material for dye-sensitized solar cell, transparent conductive base material for dye-sensitized solar cell, dye-sensitized solar cell, and dye-sensitized solar cell module according to the present invention will be described respectively.

A. Conductive Base Material for Dye-Sensitized Solar Cell

First, a conductive base material for dye-sensitized solar cell according to the present invention will be described.

The conductive base material for dye-sensitized solar cell according to the present invention (hereinafter, in this section, sometimes simply referred to as a “conductive base material”) comprises: a first metal layer made of a metal having a specific resistance of 6×10⁻⁶ Ω·m or less; and a second metal layer formed on the first metal layer, made of any one of metals of Ti, Cr, Ni, Mo, Ta, W, Nb, and Pt, and having a thickness of 500 nm or less.

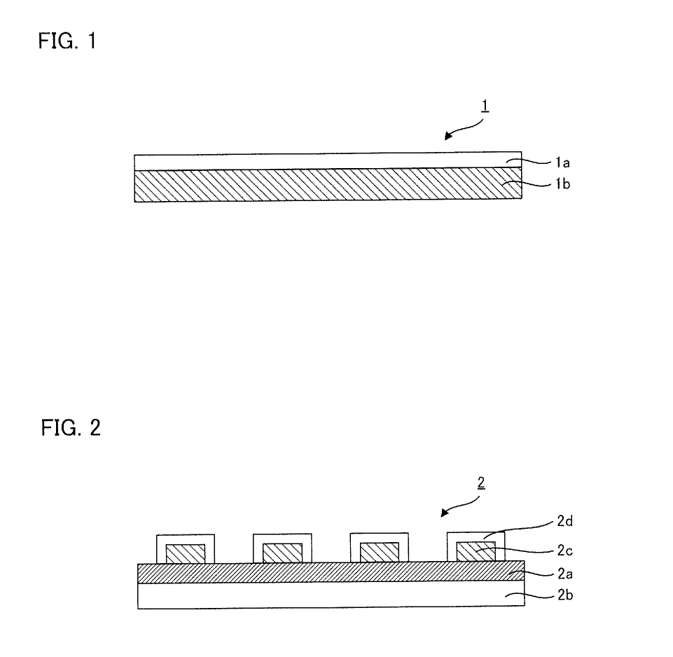

The conductive base material according to the present invention will be described with reference to FIG. 1.

FIG. 1 is a schematic sectional view of one example of the conductive base material according to the present invention. As shown in FIG. 1, a conductive base material 1 according to the present invention comprises: a first metal layer 1b made of a metal having a specific resistance of 6×10⁻⁶ Ω·m or less; and a second metal layer 1a formed on the first metal layer 1b, made of any one of metals of Ti, Cr, Ni, Mo, Ta, W, Nb, and Pt, and having a thickness of 500 nm or less.

As described above, the conductive base material according to the present invention comprises the first metal layer and the second metal layer, and therefore, when the conductive base material is used as an electrode layer constituting an electrode base material of a dye-sensitized solar cell, the electrode layer can have high resistance to corrosion by iodine ions contained in an electrolyte layer. Further, the first metal layer is made of a metal having a low specific resistance and the second metal layer is formed as a thin film, and therefore it is possible to make the electrical resistance of the conductive base material low as a whole. The use of such a conductive base material having a low electrical resistance as an electrode layer of a dye-sensitized solar cell prevents a reduction in the fill factor of the dye-sensitized solar cell, and therefore the dye-sensitized solar cell can achieve high power generation efficiency.

According to the present invention, the second metal layer can be formed by a highly-productive method such as a gas-phase plating method, a liquid-phase plating method, a printing method, or a coating method, which makes it possible to obtain a conductive base material for dye-sensitized solar cell at low cost.

Hereinbelow, the second metal layer and the first metal layer used in the present invention will be described respectively.

1. Second Metal Layer

The second metal layer used in the present invention is formed on the first metal layer (which will be described later), is made of any one of metals of Ti, Cr, Ni, Mo, Ta, W, Nb, and Pt, and has a thickness of 500 nm or less.

Here, the phrase “any one of metals of Ti, Cr, Ni, Mo, Ta, W, Nb, and Pt” refers to a single-element metal or an alloy which contains any one of the above-mentioned components by mass ratio at 70 to 100% by mass, preferably 80 to 100% by mass, particularly preferably 90 to 100% by mass.

Among these metals, the second metal layer is preferably made of Ti or Cr, and is more preferably made of Cr. This is because Cr is excellent in adhesion to the first metal layer (which will be described later), which makes it possible to form a thinner metal layer as the second metal layer on the first metal layer.

The thickness of the second metal layer needs to be 500 nm or less in order to allow the conductive base material according to the present invention to have sufficient resistance to corrosion by iodide ions and achieve satisfactory extraction of electricity from the first metal layer, but is preferably in the range of 1 to 250 nm, particularly preferably in the range of 10 to 50 nm. If the thickness of the second metal layer exceeds 500 nm, the second metal layer increases the electrical resistance of the conductive base material. Therefore, when the conductive base material having such a second metal layer with a thickness larger than 500 nm is used as an electrode layer of a dye-sensitized solar cell, it is difficult to achieve satisfactory electricity extraction efficiency. Further, there is also a possibility that cracks are formed in the second metal layer when the second metal layer is produced or used, which makes it difficult to allow the conductive base material to have sufficient resistance to corrosion by iodide ions.

The lower limit of the thickness of the second metal layer is about 1 nm. If the thickness of the second metal layer is less than 1 nm, there is a fear that it is difficult to form the second metal layer on the first metal layer (which will be described later).

A method for forming the second metal layer is not particularly limited as long as the second metal layer can be formed on the first metal layer (which will be described later) so as to have a thickness of 500 nm or less. Preferred examples of such a method include gas-phase plating methods such as sputtering, ion plating, vacuum vapor deposition, and chemical vapor deposition, liquid-phase plating methods such as electrolytic plating and nonelectrolytic plating, printing methods, and coating methods. This is because these methods are highly productive.

2. First Metal Layer

The first metal layer used in the present invention is made of a metal having a specific resistance of 6×10⁻⁶ Ω·m or less.

Here, the “metal having a specific resistance of 6×10⁻⁶ Ω·m or less” refers to a single-element metal having a specific resistance of 6×10⁻⁶ Ω·m or less or an alloy having a specific resistance of 6×10⁻⁶ Ω·m or less.

The first metal layer is not particularly limited as long as a conductive base material obtained by forming the second metal layer on the first metal layer can be used as an electrode base material of a dye-sensitized solar cell. The first metal layer may be either one having flexibility or one not having flexibility, but is preferably one having flexibility. The use of the first metal layer having flexibility makes it possible to impart flexibility to the conductive base material according to the present invention. As described above, since the conductive base material according to the present invention is used as an electrode base material of a dye-sensitized solar cell, the use of such a conductive base material having flexibility in a dye-sensitized solar cell makes it possible to impart flexibility to the dye-sensitized solar cell, thereby improving the workability of the dye-sensitized solar cell.

The flexibility of the first metal layer means that the first metal layer is bent by the application of a force of 5 KN according to a metal material bend test method specified in JIS Z 2248.

The first metal layer may be composed of only a metal layer using the above-described metal or of a base material and the metal layer formed on the base material, but is preferably composed of only the metal layer. Particularly, the first metal layer is preferably a metal foil. The use of a metal foil as the first metal layer makes it easy to prepare the first metal layer, thereby enabling a conductive base material to be obtained at low cost.

The thickness of the metal foil is preferably in the range of 5 to 300 μm, more preferably in the range of 10 to 200 μm, and particularly preferably in the range of 15 to 100 μm. If the thickness of the metal foil exceeds the above upper limit, it is difficult to impart flexibility to the conductive base material according to the present invention. On the other hand, if the thickness of the metal foil is less than the above lower limit, it is difficult to form the second metal layer on the metal foil to obtain a conductive base material.

Examples of the metal that has a specific resistance of 6×10⁻⁶ Ω·m or less and is relatively cheaply available include Al, stainless steel, Cu, Ag, and Ni. From the viewpoint of heat resistance, Al and stainless steel are preferred. Further, Al and stainless steel have a certain level of resistance to corrosion by iodide ions. Also from such a viewpoint, Al and stainless steel are preferred among the above-mentioned metals.

It is to be noted that the term “heat resistance” used herein means that the metal is not deformed or altered by the application of heat when a porous layer is formed on the conductive base material by burning.

B. Transparent Conductive Base Material for Dye-Sensitized Solar Cell

Hereinbelow, a transparent conductive base material for dye-sensitized solar cell according to the present invention (hereinafter, sometimes simply referred to as a “transparent conductive base material”) will be described.

The transparent conductive base material according to the present invention comprises: a transparent base material; a transparent electrode layer formed on the transparent base material; and an auxiliary metal layer that has a mesh metal layer formed in a mesh on the transparent electrode layer and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less.

In a case where the transparent conductive base material according to the present invention is used as an electrode base material of a dye-sensitized solar cell, the transparency of the transparent conductive base material, which is defined as the transmittance of light with a wavelength of 400 to 800 nm, is preferably 70% or more and more preferably 80% or more.

It is to be noted that the transparency of the transparent conductive base material is a value measured by a method based on JIS K7361-1:1997.

Hereinbelow, the transparent conductive base material according to the present invention will be described with reference to the drawing.

FIG. 2 is a schematic sectional view of one example of the transparent conductive base material according to the present invention. As shown in FIG. 2, a transparent conductive base material 2 according to the present invention comprises: a transparent base material 2b; a transparent electrode layer 2a formed on the transparent base material 2b; and an auxiliary metal layer that has a mesh metal layer 2c formed in a mesh on the transparent electrode layer 2a and made of a metal having a specific resistance of 6×10⁻⁶ Ω·m or less, and a second metal layer 2d formed on the mesh metal layer 2c, made of any one of metals of Ti, Cr, Ni, Mo, Ta, W, Nb, and Pt, and having a thickness of 500 nm or less.

According to the present invention, the auxiliary metal layer has the mesh metal layer and the second metal layer, and therefore can have high resistance to corrosion by iodide ions contained in an electrolyte layer. Further, the mesh metal layer is made of a metal having a low specific resistance and the second metal layer is formed as a thin film, and therefore the electrical resistance of the auxiliary metal layer can be low as a whole. Therefore, the auxiliary metal layer makes it possible to improve the efficiency of extracting electricity from the transparent electrode layer, thereby enabling a dye-sensitized solar cell having high power generation to be provided. Each of the members used in the transparent conductive base material according to the present invention will be described below.

1. Auxiliary Metal Layer

The auxiliary metal layer used in the present invention has a mesh metal layer formed in a mesh and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less. It is to be noted that the second metal layer is the same as that described above in the section “A. Conductive Base Material for Dye-Sensitized Solar Cell”, and therefore the description thereof is omitted here. The mesh metal layer will be described below.

The mesh metal layer used in the present invention is formed in a mesh on the transparent electrode layer (which will be described later) and is made of a metal having a specific resistance of 6×10⁻⁶ Ω·m or less.

The mesh shape of the mesh metal layer can be formed in, for example, a triangular lattice pattern, parallelogramic lattice pattern, or a hexagonal lattice pattern.

The thickness of the mesh metal layer is preferably in the range of 0.01 to 10 μm. If the thickness of the mesh metal layer exceeds the above upper limit, the amount of material required to form the mesh metal layer is large and it takes a long time to form the mesh metal layer, and therefore there is a fear that production efficiency is reduced and production cost is increased. On the other hand, if the thickness of the mesh metal layer is less than the above lower limit, there is a possibility that the performance of the transparent electrode layer (which will be described later) cannot be improved.

The opening ratio of the mesh metal layer used in the present invention is preferably in the range of 50 to 99.9%. If the opening ratio of the mesh metal layer is less than the above lower limit, there is a possibility that solar light cannot be sufficiently received by the transparent conductive base material so that power generation efficiency is reduced. On the other hand, if the opening ratio of the mesh metal layer exceeds the above upper limit, there is a possibility that it is difficult to improve the performance of the transparent electrode layer even when the mesh metal layer is used.

The line width and mesh pitch of the mesh metal layer are appropriately selected according to the shape of a dye-sensitized solar cell used. However, the line width of the mesh metal layer is preferably in the range of 0.02 μm to 10 mm, more preferably in the range of 1 μm to 2 mm, and particularly preferably in the range of 10 μm to 1 mm; and the mesh pitch of the mesh metal layer is preferably in the range of 1 to 500 μm, more preferably in the range of 5 to 100 μm and particularly preferably in the range of 10 to 50 μm.

The “metal having a specific resistance of 6×10⁻⁶ Ω·m or less” used for forming the mesh metal layer is the same as that described above in the section “A. Conductive Base Material for Dye-Sensitized Solar Cell”, and therefore the description thereof is omitted here.

Examples of a method for forming such a mesh metal layer include a method in which the mesh metal layer is formed by gas-phase plating method using a metal mask, a method in which a thin film made of the above-described metal is formed on the entire surface of the transparent electrode layer and is etched into a predetermined pattern, and a method in which the mesh metal layer is formed on the transparent base material or the transparent electrode layer by printing using a paste of the above-described metal.

2. Transparent Base Material

As the transparent base material used in the present invention, for example, an inorganic transparent base material or a resinous base material can be used. Among them, a resinous base material is preferred because it is lightweight, has excellent workability, and contributes to lower production cost.

Preferred examples of such a resinous base material include a polyethyleneterephthalate (PET) film, a polyester naphthalate (PEN) film, and a polycarbonate (PC) film.

Examples of the inorganic transparent base material include a synthesized quartz base material and a glass substrate.

The thickness of the transparent base material used in the present invention can be appropriately selected according to, for example, the intended use of the dye-sensitized solar cell, but is generally preferably in the range of 10 to 2000 μm, more preferably in the range of 50 to 1800 μm and particularly preferably in the range of 100 to 1500 μm.

3. Transparent Electrode Layer

The transparent electrode layer used in the present invention is not particularly limited as long as it has transparency and predetermined conductivity. Examples of a material used for forming such a transparent electrode layer include metal oxides and conductive polymeric compound materials.

Examples of the metal oxides include SnO₂, ZnO, a compound obtained by adding SnO₂ to indium oxide (ITO), fluorine-doped SnO₂ (FTC), and a compound obtained by adding ZnO to indium oxide (IZO).

On the other hand, examples of the conductive polymeric compound materials include polythiophene, polyethylenesulfonic acid (PSS), polyaniline (PA), polypyrrole, and polyethylenedioxythiophene (PEDOT). These conductive polymeric compound materials may be used in combination of two or more of them.

The transparent electrode layer used in the present invention may have either a single-layer structure or a laminated structure of two or more layers. Examples of the laminated structure of two or more layers include one obtained by laminating two or more layers made of materials having different work functions and one obtained by laminating two or more layers made of different metal oxides.

The thickness of the transparent electrode layer used in the present invention is generally preferably in the range of 5 to 2000 nm and particularly preferably in the range of 10 to 1000 nm. If the thickness of the transparent electrode layer exceeds the above upper limit, there is a case where it is difficult to uniformly form the transparent electrode layer or there is a case where the total light transmittance of the transparent electrode layer is lowered so that it is difficult to achieve satisfactory photoelectric conversion efficiency. On the other hand, if the thickness of the transparent electrode layer is less than the above lower limit, there is a possibility that the transparent electrode layer is poor in conductivity.

It is to be noted that when the transparent electrode layer is composed of two or more layers, the above-described thickness means the total thickness of all the layers.

The transparent electrode layer can be formed on the transparent base material by a method generally used for forming an electrode layer, and therefore the description of a method for forming the transparent electrode layer is omitted here.

C. Dye-Sensitized Solar Cell

Hereinbelow, a dye-sensitized solar cell according to the present invention will be described.

The dye-sensitized solar cell according to the present invention is broadly divided into two embodiments based on the structure of the electrode base materials. Each of the embodiments will be described below.

I. Dye-Sensitized Solar Cell according to First Embodiment

A dye-sensitized solar cell according to a first embodiment comprises: an oxide semiconductor electrode substrate that has: a first electrode base material functioning as an electrode, and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, wherein one of the first electrode base material and the second electrode base material has, as an electrode layer, a conductive base material for dye-sensitized solar cell (hereinafter, in this section, sometimes simply referred to as a “conductive base material”) comprising a first metal layer made of a metal having a specific resistance of 6×10⁻⁶ Ω·m or less and a second metal layer formed on the first metal layer, made of any one of metals of Ti, Cr, Ni, Mo, Ta, W, Nb, and Pt, and having a thickness of 500 nm or less; and the other is a base material having transparency.

According to the present embodiment, since one of the first electrode base material and the second electrode base material has the conductive base material as an electrode layer, the electrode layer can have high resistance to corrosion by iodide ions contained in the electrolyte layer, and is therefore less likely to be degraded with time. This makes it possible to achieve a high-quality dye-sensitized solar cell. Further, the conductive base material has a low electrical resistance, which makes it possible to prevent a reduction in the fill factor of the dye-sensitized solar cell.

The “fill factor of the dye-sensitized solar cell” is a value representing the performance of the dye-sensitized solar cell. When the internal electrical resistance of the dye-sensitized solar cell is lower, the fill factor is larger, and when the internal electrical resistance of the dye-sensitized solar cell is higher, the fill factor is smaller. The power generation efficiency of the dye-sensitized solar cell can be increased by increasing the fill factor of the dye-sensitized solar cell.

As described above, in the first embodiment, one of the first electrode base material and the second electrode base material has the conductive base material having a low electrical resistance as an electrode layer. Therefore, the internal electrical resistance of the dye-sensitized solar cell can be made low, that is, the fill factor of the dye-sensitized solar cell can be made large, which makes it possible to achieve high power generation efficiency.

It is to be noted that the fill factor of the dye-sensitized solar cell according to the present invention can be determined by measuring the current-voltage characteristics of the dye-sensitized solar cell.

The current-voltage characteristics of the dye-sensitized solar cell can be measured by, for example, applying a voltage to the dye-sensitized solar cell by means of a source measure unit (Keithley 2400™) under illumination of an artificial AM 1.5 solar light source (intensity of incident light: 100 mW/cm²).

More specifically, the dye-sensitized solar cell according to the present embodiment includes two aspects: one in which the first electrode base material has the conductive base material as an electrode layer and the second electrode base material is a base material having transparency (hereinafter, referred to as a “first aspect”), and the other in which the second electrode base material has the conductive base material as an electrode layer and the first electrode base material is a base material having transparency (hereinafter, referred to as a “second aspect”). A dye-sensitized solar cell according to a first aspect and a dye-sensitized solar cell according to a second aspect will be described below.

1. Dye-Sensitized Solar Cell according to First Aspect

In the dye-sensitized solar cell according to the first aspect, the first electrode base material has the conductive base material as an electrode layer and the second electrode base material is a base material having transparency.

The dye-sensitized solar cell according to the first aspect will be described with reference to the drawing.

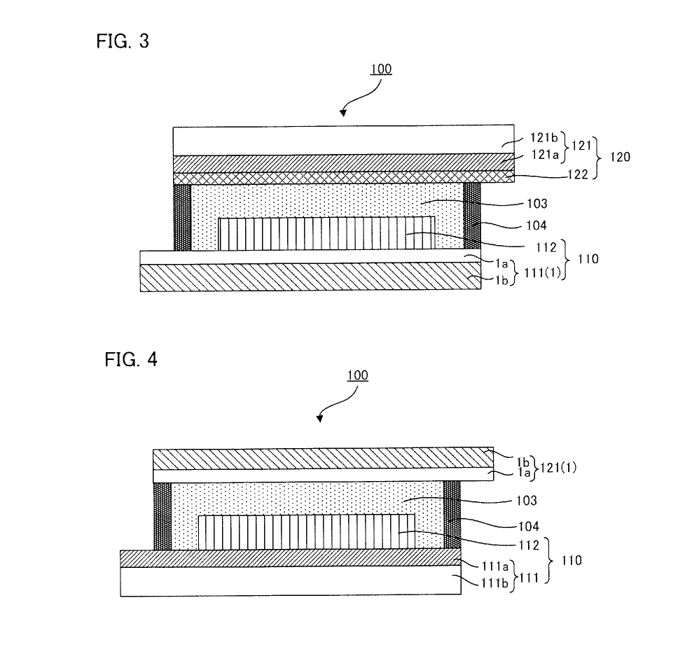

FIG. 3 is a schematic sectional view of one example of the dye-sensitized solar cell according to the first aspect. As shown in FIG. 3, a dye-sensitized solar cell 100 according to the first aspect comprises: an oxide semiconductor electrode substrate 110 that has a first electrode base material 111 having a conductive base material 1 as an electrode layer and a porous layer 112 formed on the first electrode base material 111 and containing dye-sensitizer-supported fine particles of a metal oxide semiconductor; a counter electrode substrate 120 that has a second electrode base material 121 having a transparent base material 121b and a transparent electrode layer 121a and a catalyst layer 122 formed on the transparent electrode layer 121a; and an electrolyte layer 103 that contains a redox pair and is provided between the oxide semiconductor electrode substrate 110 and the counter electrode substrate 120 arranged so that the porous layer 112 and the catalyst layer 122 are opposed to each other. The conductive base material 1 has a first metal layer 1b made of a metal having a specific resistance of 6×10⁻⁶ Ω·m or less and a second metal layer 1a formed on the first metal layer 1b, made of any one of metals of Ti, Cr, Ni, Mo, Ta, W, Nb, and Pt, and having a thickness of 500 nm or less.

As shown in FIG. 3, the ends of the dye-sensitized solar cell 100 are usually sealed with, for example, a sealing agent 104.

In the dye-sensitized solar cell according to the first aspect, the first electrode base material has the conductive base material as an electrode layer. Therefore, the dye-sensitized solar cell can achieve higher power generation efficiency. The reason for this is not clear, but may be considered as follows.

When only the first metal layer is used as a first electrode base material, it is considered that the difference in energy level between the first metal layer and the porous layer containing metal oxide semiconductor fine particles is large and therefore electrons are less likely to move between the first electrode base material and the porous layer.

On the other hand, when the conductive base material is used as a first electrode base material, it is considered that the difference in energy level between the first metal layer and the porous layer can be narrowed by the second metal layer present between the first metal layer and the porous layer, and therefore electrons are more likely to move between the first metal layer and the porous layer through the second metal layer. From this, it is considered that the efficiency of extracting electricity from the first metal layer is improved, and therefore the dye-sensitized solar cell can achieve higher power generation efficiency.

Each of the members used in the dye-sensitized solar cell according to the first aspect will be described below.

(1) Oxide Semiconductor Electrode Substrate

The oxide semiconductor electrode substrate used in the first aspect has a first electrode base material functioning as an electrode and a porous layer formed on the first electrode base material and containing dye-sensitizer-supported fine particles of a metal oxide semiconductor. The first electrode base material and the porous layer used in the first aspect will be described below in this order.

(a) First Electrode Base Material

The first electrode base material used in the first aspect has a conductive base material as an electrode layer. The conductive base material is the same as that described above in the section “A. Conductive Base Material for Dye-Sensitized Solar Cell”, and therefore the description thereof is omitted here.

(b) Porous Layer

The porous layer used in the first aspect will be described below. The porous layer used in the first aspect contains dye-sensitizer-supported fine particles of a metal oxide semiconductor, is formed on the above-mentioned first electrode base material, and is in contact with the electrolyte layer (which will be described later). It is to be noted that the dye sensitizer is supported on the surface of the metal oxide semiconductor fine particles.

The metal oxide semiconductor fine particles and the dye sensitizer used in the porous layer will be described below in this order.

(i) Metal Oxide Semiconductor Fine Particles

The metal oxide semiconductor fine particles used in the first aspect are not particularly limited as long as they are made of a metal oxide having semiconducting properties. Examples of such a metal oxide constituting the metal oxide semiconductor fine particles used in the first aspect include TiO₂, ZnO, SnO₂, ITO, ZrO₂, MgO, Al₂O₃, CeO₂, Bi₂O₃, Mn₃O₄, Y₂O₃, WO₃, Ta₂O₅, Nb₂O₅, and La₂O₃.

Among these metal oxides, TiO₂ is most preferably used as a metal oxide constituting the metal oxide semiconductor fine particles in the first aspect because of its particularly excellent semiconducting properties.

The average particle size of the metal oxide semiconductor fine particles used in the present aspect is usually preferably in the range of 1 nm to 10 μm and particularly preferably in the range of 10 to 1000 nm.

(ii) Dye Sensitizer

The dye sensitizer used in the first aspect is not particularly limited as long as it can absorb light to generate electromotive force. Examples of such a dye sensitizer include organic pigments and metal complex pigments. Examples of the organic pigments include acridine-based pigments, azo-based pigments, indigo-based pigments, quinone-based pigments, coumarin-based pigments, merocyanine-based pigments, phenylxanthene-based pigments, indoline-based pigments, and carbazole-based pigments. Among these organic pigments, indoline-based pigments and carbazole-based pigments are preferably used in the first aspect. On the other hand, as the metal complex pigments, ruthenium-based pigments are preferably used. Among the ruthenium-based pigments, ruthenium bipyridine pigments and ruthenium terpyridine pigments, which are ruthenium complexes, are particularly preferably used. This is because such ruthenium complexes can absorb light over a wide wavelength range, and therefore the wavelength range of light that can be converted into electricity can be significantly broadened.

(iii) Optional Component

The porous layer used in the first aspect may further contain an optional component other than the metal oxide semiconductor fine particles. Examples of such an optional component used in the first aspect include resins. By allowing the porous layer to contain a resin, the brittleness of the porous layer used in the first aspect can be improved.

Examples of such a resin include polyvinyl pyrrolidone, ethyl cellulose, and caprolactam.

(iv) Others

The thickness of the porous layer used in the first aspect is usually preferably in the range of 1 to 100 μm and particularly preferably in the range of 3 to 30 μm.

(2) Counter Electrode Substrate

The counter electrode substrate used in the first aspect will be described below.

The counter electrode substrate used in the first aspect has at least a second electrode base material functioning as an electrode. The second electrode base material will be described below.

(a) Second Electrode Base Material

The second electrode base material used in the first aspect is a base material having transparency.

Such a base material having transparency usually has a transparent base material and a transparent electrode layer formed on the transparent base material. The transparent base material and the transparent electrode layer are the same as those described above in the section “B. Transparent Conductive Base Material for Dye-Sensitized Solar Cell”, and therefore the description thereof is omitted here.

As described above, the second electrode base material used in the first aspect is not particularly limited as long as it has the transparent base material and the transparent electrode layer, and if necessary, may further have an optional member. As such an optional member, for example, an auxiliary electrode layer can be mentioned.

The auxiliary electrode layer is an electrode layer formed in a mesh using a conductive material. By using the auxiliary electrode layer together with the above-mentioned transparent electrode layer, it is possible to enhance the power generation efficiency of the dye-sensitized solar cell according to the first aspect.

The position of the auxiliary electrode layer used in the first aspect is not particularly limited as long as it can be used together with the transparent electrode layer to enhance the power generation efficiency of the dye-sensitized solar cell according to the first aspect. For example, the auxiliary electrode layer may be formed on the transparent electrode layer formed on the transparent base material or may be formed between the transparent base material and the transparent electrode layer. In the first aspect, the auxiliary electrode layer is preferably formed between the transparent base material and the transparent electrode layer. This is because the auxiliary electrode layer is less likely to come into contact with iodide ions contained in the electrolyte layer as compared to a case where the auxiliary electrode layer is formed on the transparent electrode layer formed on the transparent base material.

The material of the auxiliary electrode layer used in the first aspect is not particularly limited as long as it can enhance the power generation efficiency of the dye-sensitized solar cell according to the first aspect.

It is to be noted that in the first aspect, even when the auxiliary electrode layer is formed on the transparent base material and the transparent electrode layer is further formed on the auxiliary electrode layer, some iodide ions contained in the electrolyte layer (which will be described later) penetrate through the transparent electrode layer and then come into contact with the auxiliary electrode layer. For this reason, the auxiliary electrode layer is preferably made of a material having resistance to corrosion by iodide ions.

Specific examples of such a material for forming the auxiliary electrode layer include titanium, tungsten, molybdenum, chromium, and platinum. However, metal species commonly used such as aluminum, nickel, copper, iron, and silver and alloys thereof can also be used as long as they are subjected to surface treatment, such as plating, to improve resistance to corrosion.

Such an auxiliary electrode layer can be formed by the method for forming a mesh metal layer described above in the section “B. Transparent Conductive Base Material for Dye-Sensitized Solar Cell”, and therefore the description of a method for forming the auxiliary electrode layer is omitted here.

The mesh shape, opening ratio, mesh pitch, and line width of the auxiliary electrode layer used in the first aspect are the same as those described above with reference to the mesh metal layer in the section “B. Transparent Conductive Base Material for Dye-Sensitized Solar Cell”, and therefore the description thereof is omitted here.

If necessary, the second electrode base material used in the first aspect may further have an optional member other than the auxiliary electrode layer.

As the second electrode base material used in the first aspect, the transparent conductive base material for dye-sensitized solar cell described above in the section “B. Transparent Conductive Base Material for Dye-Sensitized Solar Cell” may be used instead of the above-described base material having transparency.

(b) Other Members

The counter electrode substrate used in the first aspect is not particularly limited as long as it has at least the second electrode base material, and if necessary, may further have an optional member. An example of such an optional member includes a catalyst layer.

By forming a catalyst layer on the second electrode base material, it is possible to further enhance the power generation efficiency of the dye-sensitized solar cell according to the first aspect. Examples of such a catalyst layer include, but are not limited to, one formed by vapor-depositing Pt on the second electrode base material and one made of polyethylene dioxythiophene (PEDOT), polystyrenesulfonic acid (PSS), polyaniline (PA), paratoluenesulfonic acid (PTS), or a mixture of two or more of them.

The thickness of such a catalyst layer is preferably in the range of 1 nm to 10 μm, more preferably in the range of 10 to 1000 nm and particularly preferably in the range of 10 to 500 nm.

(3) Electrolyte Layer

The electrolyte layer used in the first aspect is formed between the oxide semiconductor electrode substrate and the counter electrode substrate, and contains a redox pair.

The redox pair contained in the electrolyte layer used in the first aspect is a combination of iodine and iodide. Examples of such a combination of iodine and iodide include a combination of a metal iodide, such as LiI, NaI, KI, or CaI₂, and I₂.

The electrolyte layer used in the first aspect may contain, as compounds other than the redox pair, a cross-linking agent, a photopolymerization initiator, a thickener, an additive such as a room temperature fused salt, and the like.

The electrolyte layer used in the first aspect may be in any form of gel, solid, or liquid.

(4) Other Members

The dye-sensitized solar cell according to the first aspect is not particularly limited as long as it comprises the oxide semiconductor electrode substrate, the counter electrode substrate, and the electrolyte layer, and if necessary, may further comprise an optional member. An example of such an optional member includes a sealing agent for sealing the ends of the dye-sensitized solar cell.

2. Dye-Sensitive Solar-Cell according to Second Aspect

Hereinbelow, the dye-sensitized solar cell according to the second aspect will be described.

In the dye-sensitized solar cell according to the second aspect, the second electrode base material has the conductive base material as an electrode layer and the first electrode base material is a base material having transparency.

The dye-sensitized solar cell according to the second aspect will be described with reference to the drawing.

FIG. 4 is a schematic sectional view of one example of the dye-sensitized solar cell according to the second aspect. As shown in FIG. 4, a dye-sensitized solar cell 100 according to the second aspect comprises: an oxide semiconductor electrode substrate 110 that has: a first electrode base material 111 having a transparent base material 111b and a transparent electrode layer 111a formed on the transparent base material 111b, and a porous layer 112 formed on the transparent electrode layer 111a and containing dye-sensitizer-supported fine particles of a metal oxide semiconductor; a counter electrode substrate that has a second electrode base material 121 having a conductive base material 1 as an electrode layer; and an electrolyte layer 103 that contains a redox pair and is provided between the oxide semiconductor electrode substrate 110 and the counter electrode substrate arranged so that the porous layer 112 and the second electrode base material 121 are opposed to each other. The conductive base material 1 has a first metal layer 1b made of a metal having a specific resistance of 6×10⁻⁶ Ω·m or less and a second metal layer 1a formed on the first metal layer 1b, made of any one of metals of Ti, Cr, Ni, Mo, Ta, W, Nb, and Pt, and having a thickness of 500 nm or less. The porous layer 112 is provided so as to be opposed to the second metal layer 1a.

As shown in FIG. 4, the ends of the dye-sensitized solar cell 100 are usually sealed with, for example, a sealing agent 104.

The electrolyte layer and other members used in the second aspect are the same as those described above in the section “1. Dye-Sensitized Solar Cell according to First Aspect”, and therefore the description thereof is omitted here.

The oxide semiconductor electrode substrate and the counter electrode substrate used in the second aspect will be described below.

(1) Counter Electrode Substrate

The counter electrode substrate used in the second aspect has at least a second electrode base material.

In the second aspect, the second electrode base material has a conductive base material as an electrode layer. The conductive base material is the same as that described above in the section “A. Conductive Base Material for Dye-Sensitized Solar Cell”, and therefore the description thereof is omitted here.

In the second aspect, the second metal layer formed in the conductive base material has the same function and effect as a catalyst layer. Therefore, the counter electrode substrate used in the second aspect does not always need to have a catalyst layer provided separately from the conductive base material, but may have a catalyst layer in order to further enhance power generation efficiency. The catalyst layer is the same as that described above in the section “1. Dye-Sensitized Solar Cell according to First Aspect”, and therefore the description thereof is omitted here.

(2) Oxide Semiconductor Electrode Substrate

The oxide semiconductor electrode substrate used in the second aspect has a first electrode base material functioning as an electrode and a porous layer formed on the first electrode base material and containing dye-sensitizer-supported fine particles of a metal oxide semiconductor. In the second aspect, the first electrode base material is a base material having transparency.

The base material having transparency is the same as that described above in the section “1. Dye-Sensitized Solar Cell according to First Aspect”, and therefore the description thereof is omitted here. Alternatively, the first electrode base material may be the transparent conductive base material for dye-sensitized solar cell described above in the section “B. Transparent Conductive Base Material for Dye-Sensitized Solar Cell”.

The porous layer used in the second aspect is the same as that described above in the section “1. Dye-Sensitized Solar Cell according to First Aspect”, and therefore the description thereof is omitted here.

3. Others

As the dye-sensitized solar cell according to the first embodiment, the dye-sensitized solar cell according to the first aspect is more preferred than the dye-sensitized solar cell according to the second aspect because of its higher power generation efficiency.

II. Dye-Sensitized Solar Cell according to Second Embodiment

A dye-sensitized solar cell according to a second embodiment comprises: an oxide semiconductor electrode substrate that has: a first electrode base material functioning as an electrode and a porous layer formed on the first electrode base material and containing dye-sensitizer-supported fine particles of a metal oxide semiconductor; a counter electrode substrate that has at least a second electrode base material functioning as an electrode; and an electrolyte layer that contains a redox pair and is provided between the oxide semiconductor electrode substrate and the counter electrode substrate arranged so that the porous layer and the second electrode base material are opposed to each other, wherein at least one of the first electrode base material and the second electrode base material is a transparent conductive base material for dye-sensitized solar cell (hereinafter, in this section, sometimes simply referred to as a “transparent conductive base material”) that comprises a transparent base material, a transparent electrode layer formed on the transparent base material, and an auxiliary metal layer having a mesh metal layer formed in a mesh on the transparent electrode layer and made of a metal having a specific resistance of 6×10⁻⁶ Ω·m or less and a second metal layer formed on the mesh metal layer, made of any one of metals of Ti, Cr, Ni, Mo, Ta, W, Nb, and Pt, and having a thickness of 500 nm or less.

According to the second embodiment, since at least one of the first electrode base material and the second electrode base material is the transparent conductive base material, high resistance to corrosion by iodide ions contained in the electrolyte layer can be achieved and a reduction in the fill factor of the dye-sensitized solar cell can be prevented. This makes it possible to achieve a high-quality dye-sensitized solar cell having high power generation efficiency.

The fill factor of the dye-sensitized solar cell according to the second embodiment is the same as that described above in the section “I. Dye-Sensitized Solar Cell according to First Embodiment”, and therefore the description thereof is omitted here.

More specifically, the dye-sensitized solar cell according to the second embodiment includes two aspects: one in which at least the first electrode base material is the transparent conductive base material (hereinafter, referred to as a “third aspect”) and the other in which at least the second electrode base material is the transparent conductive base material (hereinafter, referred to as a “fourth aspect”). A dye-sensitized solar cell according to a third aspect and a dye-sensitized solar cell according to a fourth aspect will be described below.

1. Dye-Sensitized Solar Cell according to Third Aspect

In the dye-sensitized solar cell according to the third aspect, at least the first electrode base material is the transparent conductive base material.

The dye-sensitized solar cell according to the third aspect will be described with reference to the drawing.

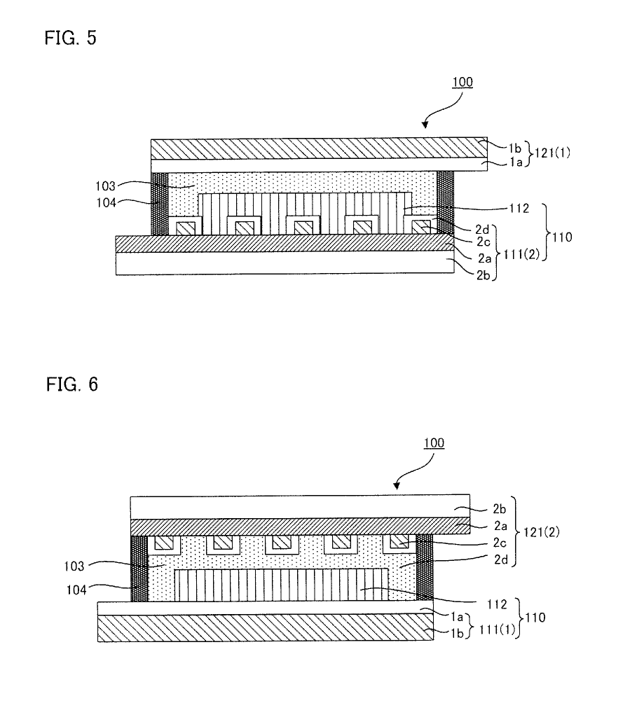

FIG. 5 is a schematic sectional view of one example of the dye-sensitized solar cell according to the third aspect. As shown in FIG. 5, a dye-sensitized solar cell 100 according to the third aspect comprises: an oxide semiconductor electrode substrate 110 that has a first electrode base material 111 constituted from a transparent conductive base material 2 and a porous layer 112 formed on the first electrode base material 111 and containing dye-sensitizer-supported fine particles of a metal oxide semiconductor; a counter electrode substrate constituted from a second electrode base material 121 that has, as an electrode layer, a conductive base material 1 having a first metal layer 1b and a second metal layer 1a; and an electrolyte layer 103 that contains a redox pair and is provided between the oxide semiconductor electrode substrate 110 and the counter electrode substrate arranged so that the porous layer 112 and the second metal layer 1a of the conductive base material 1 are opposed to each other. The transparent conductive base material 2 has a transparent base material 2b, a transparent electrode layer 2a formed on the transparent base material 2b, a mesh metal layer 2c formed in a mesh on the transparent electrode layer 2a and made of a metal having a specific resistance of 6×10⁻⁶ Ω·m or less, and a second metal layer 2d formed on the mesh metal layer 2c, made of any one of metals of Ti, Cr, Ni, Mo, Ta, W, Nb, and Pt, and having a thickness of 500 nm or less. It is to be noted that the conductive base material 1 is the same as that described above with reference to FIG. 3, and therefore the description thereof is omitted here.

As shown in FIG. 5, the ends of the dye-sensitized solar cell 100 are usually sealed with, for example, a sealing agent 104.

According to the third aspect, the first electrode base material has the transparent conductive base material as an electrode layer, which makes it possible to further enhance the power generation efficiency of the dye-sensitized solar cell according to the third aspect. The reason for this is the same as that described above in the section “1. Dye-Sensitized Solar Cell according to First Aspect”, and therefore the description thereof is omitted here.

Each of the members used in the dye-sensitized solar cell according to the third aspect will be described below.

(1) Oxide Semiconductor Electrode Substrate

The oxide semiconductor electrode substrate used in the third aspect has a first electrode base material and a porous layer formed on the first electrode base material and containing dye-sensitizer-supported fine particles of a metal oxide semiconductor. The porous layer is the same as that described above in the section “I. Dye-Sensitized Solar Cell according to First Embodiment”, and therefore the description thereof is omitted here.

The first electrode base material used in the third aspect is a transparent conductive base material.

The transparent conductive base material is the same as that described above in the section “B. Transparent Conductive Base Material for Dye-Sensitized Solar Cell”, and therefore the description thereof is omitted here.

(2) Counter Electrode Substrate

The counter electrode substrate used in the third aspect has at least a second electrode base material.

The dye-sensitized solar cell according to the third aspect has the first electrode base material as a base material having transparency, and therefore the second electrode base material may be either one having transparency or one not having transparency. For example, when a base material having transparency is used as the second electrode base material, such a base material is the same as the second electrode base material described above in the section “1. Dye-Sensitized Solar Cell according to First Aspect”, and therefore the description thereof is omitted here.

On the other hand, when a base material not having transparency is used as the second electrode base material, a substrate including a metal layer having resistance to corrosion by iodide ions can be used as the second electrode base material. As such a substrate, the conductive base material for dye-sensitized solar cell described above in the section “A. Conductive Base Material for Dye-Sensitized Solar Cell” is preferably used. This is because the conductive base material for dye-sensitized solar cell can be formed at low cost, has high resistance to corrosion by iodide ions, and can prevent a reduction in the conversion efficiency of the dye-sensitized solar cell.

Further, when the conductive base material for dye-sensitized solar cell or the transparent conductive base material is used as the second electrode base material, the second metal layer has the same function and effect as the above-described catalyst layer. Therefore, the dye-sensitized solar cell according to the third aspect does not always need to have a catalyst layer, but may have a catalyst layer in order to further enhance the power generation efficiency thereof. The catalyst layer is the same as that described above in the section “I. Dye-Sensitized Solar Cell according to First Embodiment”, and therefore the description thereof is omitted here.

(3) Electrolyte Layer

The electrolyte layer used in the third aspect is the same as that described above in the section “I. Dye-Sensitized Solar Cell according to First Embodiment”, and therefore the description thereof is omitted here.

2. Dye-Sensitized Solar Cell according to Fourth Aspect

In the dye-sensitized solar cell according to the fourth aspect, at least the second electrode base material is the transparent conductive base material.

The dye-sensitized solar cell according to the fourth aspect will be described with reference to the drawing.

FIG. 6 is a schematic sectional view of one example of the dye-sensitized solar cell according to the fourth aspect. As shown in FIG. 6, a dye-sensitized solar cell 100 according to the fourth aspect comprises: an oxide semiconductor electrode substrate 110 that has a first electrode base material 111 having a conductive base material 1 as an electrode layer and a porous layer 112 formed on the first electrode base material 111 and containing dye-sensitizer-supported fine particles of a metal oxide semiconductor; a counter electrode substrate that has a second electrode base material 121 constituted from a transparent conductive base material 2; and an electrolyte layer 103 that contains a redox pair and is provided between the oxide semiconductor electrode substrate 110 and the counter electrode substrate arranged so that the porous layer 112 and the transparent conductive base material 2 are opposed to each other. The transparent conductive base material 2 has a transparent base material 2b, a transparent electrode layer 2a formed on the transparent base material 2b, a mesh metal layer 2c formed in a mesh on the transparent electrode layer 2a and made of a metal having a specific resistance of 6×10⁻⁶ Ω·m or less, and a second metal layer 2d formed on the mesh metal layer 2c, made of any one of metals of Ti, Cr, Ni, Mo, Ta, N, Nb, and Pt, and having a thickness of 500 nm or less. It is to be noted that the conductive base material 1 is the same as that described above with reference to FIG. 3, and therefore the description thereof is omitted here.

As shown in FIG. 6, the ends of the dye-sensitized solar cell 100 are usually sealed with, for example, a sealing agent 104.

Each of the members used in the dye-sensitized solar cell according to the fourth aspect will be described below.

(1) Counter Electrode Substrate

The counter electrode substrate used in the fourth aspect has at least a second electrode base material. In the fourth aspect, the second electrode base material is a transparent conductive base material.

The transparent conductive base material used in the fourth aspect is the same as that described above in the section “B. Transparent Conductive Base Material for Dye-Sensitized Solar Cell”, and therefore the description thereof is omitted here.

Further, in the fourth aspect, the second metal layer of the transparent conductive base material has the same function and effect as the above-described catalyst layer, and therefore the dye-sensitized solar cell according to the fourth aspect does not always need to have a catalyst layer, but may have a catalyst layer in order to further enhance the power generation efficiency thereof.

(2) Oxide Semiconductor Electrode Substrate

The oxide semiconductor electrode substrate used in the fourth aspect has a first electrode base material and a porous layer formed on the first electrode base material and containing dye-sensitizer-supported fine particles of a metal oxide semiconductor. The porous layer is the same as that described above in the section “I. Dye-Sensitized Solar Cell according to First Embodiment”, and therefore the description thereof is omitted here.

The dye-sensitized solar cell according to the fourth aspect has the second electrode base material as a base material having transparency, and therefore the first electrode base material may be either one having transparency or one not having transparency. For example, when a base material having transparency is used as the first electrode base material, such a base material is the same as the first electrode base material described above in the section “2. Dye-Sensitized Solar Cell according to Second Aspect”, and therefore the description thereof is omitted here.

On the other hand, when a base material not having transparency is used as the first electrode base material, a substrate including a metal layer having resistance to corrosion by iodide ions can be used as the first electrode base material. As such a substrate, the conductive base material for dye-sensitized solar cell described above in the section “A. Conductive Base Material for Dye-Sensitized Solar Cell” is preferably used. This is because the conductive base material for dye-sensitized solar cell can be formed at low cost, has high resistance to corrosion by iodide ions, and can prevent a reduction in the conversion efficiency of the dye-sensitized solar cell.

(3) Electrolyte Layer

The electrolyte layer used in the fourth aspect is the same as that described above in the section “I. Dye-Sensitized Solar Cell according to First Embodiment”, and therefore the description thereof is omitted here.

3. Others

As the dye-sensitized solar cell according to the present invention, the dye-sensitized solar cell according to the third aspect is more preferred than the dye-sensitized solar cell according to the fourth aspect because of its higher power generation efficiency.

III. Others

A method for producing the dye-sensitized solar cell according to the present invention is not particularly limited as long as a dye-sensitized solar cell having such a structure as described above can be produced. Examples of such a method include: one in which the oxide semiconductor electrode substrate and the counter electrode substrate are arranged so that the porous layer and the second electrode base material are opposed to each other, and are sealed with a sealing agent, and then a liquid or gel electrolyte is introduced into the space between the oxide semiconductor electrode substrate and the counter electrode substrate to form an electrolyte layer; and one in which a solid material for forming an electrolyte layer is applied onto the porous layer of the oxide semiconductor electrode substrate and dried to form a solid electrolyte layer, and then the oxide semiconductor electrode substrate and the counter electrode substrate are arranged so that the solid electrolyte layer and the second electrode base material are opposed to and in contact with each other.

It is to be noted that these methods for producing the dye-sensitized solar cell according to the present invention are merely illustrative, and in the present invention, other conventional methods for producing a dye-sensitized solar cell may be used.

D. Dye-Sensitized Solar Cell Module

A dye-sensitized solar cell module according to the present invention includes the two or more interconnected dye-sensitized solar cells described above in the section “C. Dye-Sensitized Solar Cell”.

The dye-sensitized solar cell module according to the present invention includes two embodiments: one using the dye-sensitized solar cells described above in the section “I. Dye-Sensitized Solar Cell according to First Embodiment” (hereinafter, referred to as a “dye-sensitized solar cell module according to a third embodiment”) and the other using the dye-sensitized solar cells described above in the section “II. Dye-Sensitized Solar Cell according to Second Embodiment” (hereinafter, referred to as a “dye-sensitized solar cell module according to a fourth embodiment”). It is to be noted that in the following description, the conductive base material for dye-sensitized solar cell and the transparent conductive base material for dye-sensitized solar cell are sometimes simply referred to as a “conductive base material” and a “transparent conductive base material”, respectively.

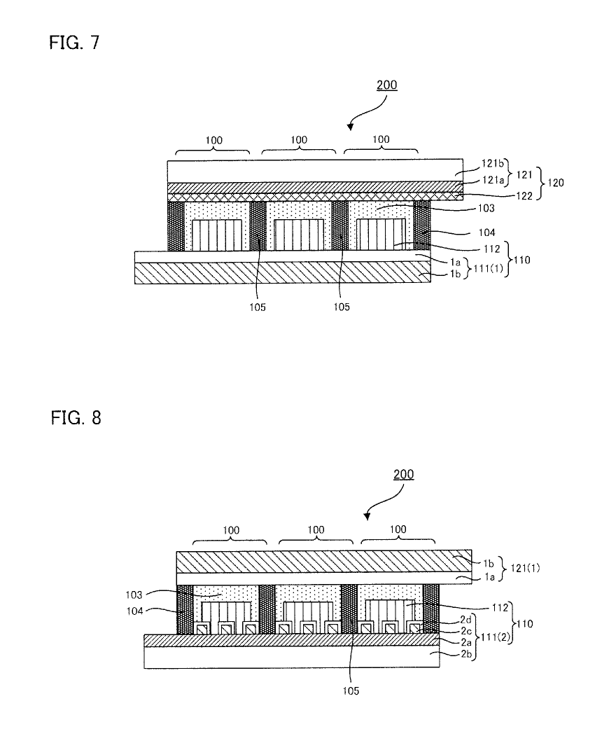

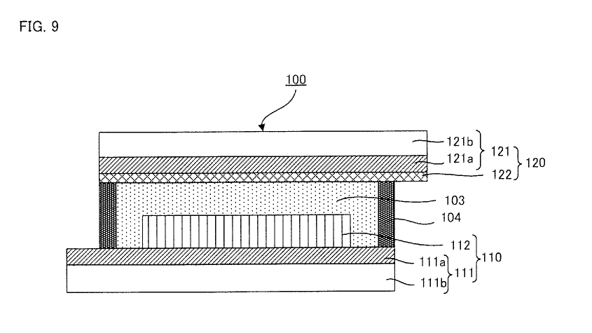

A dye-sensitized solar cell module according to a third embodiment of the present invention will be described with reference to the drawing. FIG. 7 is a schematic sectional view of one example of the dye-sensitized solar cell module according to the third embodiment of the present invention. A dye-sensitized solar cell module 200 according to the third embodiment of the present invention comprises the two or more dye-sensitized solar cells 100 interconnected in parallel, each of the dye-sensitized solar cells 100 comprising: an oxide semiconductor electrode substrate 110 that has a first electrode base material 111 having a conductive base material 1 as an electrode layer and a porous layer 112 formed on the first electrode base material 111 and containing dye-sensitizer-supported fine particles of a metal oxide semiconductor; a counter electrode substrate 120 that has a second electrode base material 121 having a transparent base material 121b and a transparent electrode layer 121a and a catalyst layer 122 formed on the transparent electrode layer 121a; and an electrolyte layer 103 that contains a redox pair and is provided between the oxide semiconductor electrode substrate 110 and the counter electrode substrate 120 arranged so that the porous layer 112 and the catalyst layer 122 are opposed to each other. The conductive base material 1 is the same as that described above with reference to FIG. 3, and therefore the description thereof is omitted here.

As shown in FIG. 7, the ends of the dye-sensitized solar cell module 200 are usually sealed with, for example, a sealing agent 104, and a partition wall 105 is provided in each gap between the adjacent dye-sensitized solar cells 100. It is to be noted that in FIG. 7, the first electrode base material has the conductive base material 1 as an electrode layer and the second electrode base material is a base material having transparency, but, although not shown, the first electrode base material may be a base material having transparency and the second electrode base material may be the conductive base material 1. Further, although not shown, the dye-sensitized solar cell module according to the third embodiment of the present invention may be configured so that the two or more dye-sensitized solar cells 100 are interconnected in series.

A dye-sensitized solar cell module according to a fourth embodiment of the present invention will be described with reference to the drawing. FIG. 8 is a schematic sectional view of one example of the dye-sensitized solar cell module according to the fourth embodiment of the present invention. A dye-sensitized solar cell module 200 according to the fourth embodiment of the present invention comprises the two or more dye-sensitized solar cells 100 interconnected in parallel, each of the dye-sensitized solar cells 100 comprising: an oxide semiconductor electrode substrate 110 that has a first electrode base material 111 constituted from a transparent conductive base material 2 and a porous layer 112 formed on the first electrode base material 111 and containing dye-sensitizer-supported fine particles of a metal oxide semiconductor; a counter electrode substrate constituted from a second electrode base material 121 that has, as an electrode layer, a conductive base material 1 having a first metal layer 1b and a second metal layer 1a; and an electrolyte layer 103 that contains a redox pair and is provided between the oxide semiconductor electrode substrate 110 and the counter electrode substrate arranged so that the porous layer 112 and the second metal layer 1a of the conductive base material 1 are opposed to each other. The transparent conductive base material 2 is the same as that described above with reference to FIG. 5, and therefore the description thereof is omitted here. The conductive base material 1 is the same as that described above with reference to FIG. 3, and therefore the description thereof is omitted here.

As shown in FIG. 8, the ends of the dye-sensitized solar cell module 200 are usually sealed with, for example, a sealing agent 104, and the partition wall 105 is provided in each gap between the adjacent dye-sensitized solar cells 100.

It is to be noted that in FIG. 8, the transparent conductive base material 2 is used as the first electrode base material 111 and the conductive base material 1 is used as the second electrode base material 121, but, although not shown, the dye-sensitized solar cell module according to the present invention is not limited to the above embodiment as long as at least one of the first electrode base material and the second electrode base material is the transparent conductive base material. Further, although not shown, the dye-sensitized solar cell module according to the fourth embodiment of the present invention may be configured so that the two or more dye-sensitized solar cells are interconnected in series.

According to the present invention, it is possible to provide a high-quality dye-sensitized solar cell module by using the dye-sensitized solar cells according to any of the foregoing embodiments because the electrode base material used in the dye-sensitized solar cells is less likely to suffer from corrosion by iodide ions contained in the electrolyte layer, and is therefore less likely to be degraded with time. Further, the dye-sensitized solar cells have high power generation efficiency, which also makes it possible to provide a high-quality dye-sensitized solar cell module.

The dye-sensitized solar cells used in the present invention are the same as those described above in the section “C. Dye-Sensitized Solar Cell”, and therefore the description thereof is omitted here.

In the present invention, the two or more dye-sensitized solar cells may be interconnected in any manner as long as a desired electromotive force can be generated by the dye-sensitized solar cell module according to the present invention. For example, the dye-sensitized solar cells may be interconnected in series or in parallel.

It is to be noted that the present invention is not limited to the foregoing embodiments. The foregoing embodiments are merely illustrative, and any embodiment that has substantially the same structure as the technical concept described in the appended claims of the present invention and demonstrates the same functions and effects are included in the technical scope of the present invention.

### EXAMPLES

Hereinbelow, the present invention will be described more specifically with reference to the following examples.

### Example 1

A 50 μm-thick stainless steel base material (SUS304, specific resistance: 0.7×10⁻⁶ Ω·m) was prepared as a first metal layer, and a conductive base material for dye-sensitized solar cell was obtained by forming a 15 nm-thick Cr layer as a second metal layer on the stainless steel base material by vacuum vapor deposition.

An ink was prepared by dispersing TiO₂ fine particles (P25™ manufactured by Nippon Aerosil Co., Ltd.) in ethanol, and a coating liquid for forming a porous layer was obtained by adding polyvinyl pyrrolidone (K-90™ manufactured by Nippon Shokubai Co., Ltd.) to the ink to achieve a solid content of 5%. Then, the coating liquid for forming a porous layer was applied with a doctor blade on an area of 10 mm×10 mm on the Cr layer of the conductive base material for dye-sensitized solar cell used as a first electrode base material and was then dried at 120° C. to obtain a 7 μm-thick layer for forming a porous layer. Then, a pressure of 0.1 t/cm was applied onto the layer for forming a porous layer with a pressing machine, and then the pressed layer for forming a porous layer was burned at 500° C. for 30 minutes.

A dye-sensitizer solution was prepared by dissolving an organic pigment (D358™ manufactured by Mitsubishi Paper Mills Limited) in a 1:1 mixed solvent of acetonitrile and t-butanol to achieve a concentration of 3.0×10⁻⁴ mol/L, and then the layer for forming a porous layer was immersed in the dye-sensitizer solution for 3 hours. After the immersion, the layer for forming a porous layer was taken out of the dye-sensitizer solution, washed with acetonitrile to remove the dye-sensitizer solution therefrom, and dried in air. In this way, a porous layer was formed to obtain an oxide semiconductor electrode substrate.

0.14 g of cationized hydroxycellulose (Jellner QH200™ manufactured by Daicel Chemical Industries, Ltd.) was dissolved in 2.72 g of ethanol to prepare a solution, and then 0.043 g of potassium iodide was dissolved in the solution under stirring. Then, 0.18 g of 1-ethyl-3-methylimidazolium tetracyanoborate (EMIm-B(CN)₄), 0.5 g of 1-propyl-3-methylimidazolium iodide (PMIm-I), and 0.025 g of I₂ were dissolved in the solution under stirring to prepare a coatable electrolyte solution.

A PEN film was prepared as a conductive base (transparent base material), and a second electrode base material was prepared by forming an ITO layer as a transparent electrode layer on the PEN film. Then, 13 Å of platinum (transmittance: 72%) was laminated on the ITO layer to form a catalyst layer. In this way, a counter electrode substrate was obtained.

The electrolyte solution was applied on the porous layer (10 mm×10 mm) of the oxide semiconductor electrode substrate with a doctor blade and dried at 100° C. to form an electrolyte layer. The oxide semiconductor electrode substrate and the counter electrode substrate were laminated together so that the electrolyte layer and the catalyst layer were opposed to each other and tightened with clips to obtain a dye-sensitized solar cell.

### Example 2

A dye-sensitized solar cell was produced in the same manner as in Example 1 except that the second metal layer was changed to a 50 nm-thick Cr layer.

### Example 3

A dye-sensitized solar cell was produced in the same manner as in Example 1 except that the second metal layer was changed to a 15 nm-thick Ti layer.

### Example 4

A dye-sensitized solar cell was produced in the same manner as in Example 1 except that the second metal layer was changed to a 50 nm-thick Ti layer.

### Example 5

A dye-sensitized solar cell was produced in the same manner as in Example 1 except that the second metal layer was changed to a 500 nm-thick Ti layer.

### Example 6

A dye-sensitized solar cell was produced in the same manner as in Example 1 except that the second metal layer was changed to a 250 nm-thick Ti layer.

### Comparative Example 1

A dye-sensitized solar cell was produced in the same manner as in Example 1 except that the first electrode base material was changed to a 50 μm-thick stainless steel base material (SUS304, specific resistance: 0.7×10⁻⁶ Ω·m).

### Comparative Example 2

A dye-sensitized solar cell was produced in the same manner as in Example 1 except that the first electrode base material was changed to a 50 μm-thick Ti base material (specific resistance: 0.7×10⁻⁶ Ω·m).

### Comparative Example 3

A dye-sensitized solar cell was produced in the same manner as in Example 1 except that the second metal layer was changed to a 1 μm-thick Ti layer.

### EVALUATIONS

The battery performance of the dye-sensitized solar cells produced in Examples 1 to 6 and Comparative Examples 1 to 3 was evaluated in the following manner.

The current-voltage characteristics of each of the dye-sensitized solar cells were measured by applying a voltage thereto by means of a source measure unit (Keithley 2400™) under illumination of an artificial AM 1.5 solar light source (incident light intensity 100 mW/cm²). Then, the conversion efficiency and fill factor of each of the dye-sensitized solar cells were determined from the measured current-voltage characteristics. It is to be noted that, during the measurement, the artificial solar light was allowed to enter each of the dye-sensitized solar cells from the counter electrode substrate side, and that the area of the porous layer used for the measurement was 1 cm² (10 mm×10 mm).

The corrosion resistance of the conductive base material of each of the dye-sensitized solar cells was evaluated in the following manner. Each of the dye-sensitized solar cells was stored in an oven at a temperature of 65° C. and a humidity of 85% R.H. for 120 hours, and was then decomposed to remove the porous layer. Then, the surface of the exposed conductive base material was visually observed to evaluate the presence or absence of metal corrosion according to the following criteria:

o: No corrosion was observed;

x: Corrosion was observed.

The evaluation results are shown in Table 1.

Further, after the second metal layer was formed, the surface of the conductive base material was visually observed to evaluate the presence or absence of cracks according to the following criteria:

o: No cracks were observed;

x: Cracks were observed.

The evaluation results are shown in Table 1. It is to be noted that the evaluation of the presence or absence of cracks was not performed on the conductive base materials used in Comparative Examples 2 and 3 because no second metal layer was formed in Comparative Examples 2 and 3.

TABLE 1

| | | | | | | | Comparative | Comparative | Comparative |
|---|---|---|---|---|---|---|---|---|---|
| | Example 1 | Example 2 | Example 3 | Example 4 | Example 5 | Example 6 | Example 1 | Example 2 | Example 3 |
| Conversion | 3.4 | 3.3 | 3.3 | 3.4 | 3.0 | 3.2 | 0.1 | 3.5 | — |
| Efficiency | | | | | | | | | |
| (%) | | | | | | | | | |
| Short-Circuit | 6.81 | 6.72 | 6.94 | 7.03 | 6.4 | 6.8 | 0.15 | 8.06 | — |
| Current | | | | | | | | | |
| (mA/cm²) | | | | | | | | | |
| Open-Circuit | 0.78 | 0.78 | 0.78 | 0.78 | 0.78 | 0.78 | 0.73 | 0.77 | — |
| Voltage (V) | | | | | | | | | |
| Fill Factor | 0.64 | 0.63 | 0.61 | 0.62 | 0.6 | 0.61 | 0.52 | 0.56 | — |
| (—) | | | | | | | | | |
| Corrosion | ◯ | ◯ | ◯ | ◯ | ◯ | ◯ | X | ◯ | — |
| Resistance | | | | | | | | | |
| Presence or | ◯ | ◯ | ◯ | ◯ | ◯ | ◯ | — | — | X |
| Absence of | | | | | | | | | |
| Cracks | | | | | | | | | |

As can be seen from Table 1, the use of a conductive base material for dye-sensitized solar cell obtained by forming a second metal layer made of a metal such as Ti or Cr and having a thickness of 500 nm or less on a first metal layer made of a metal having a specific resistance of 6×10⁻⁶ Ω·m or less as an electrode base material of a dye-sensitized solar cell makes it possible to prevent a reduction in the fill factor of the dye-sensitized solar cell, and therefore such a dye-sensitized solar cell has high power generation efficiency and high corrosion resistance and is less likely to be degraded with time. It is to be noted that the current-voltage characteristics of the dye-sensitized solar cell of Comparative Example 3 could not be measured. The reason for this may be that cracks were formed in the second metal layer.

What is claimed is:

1. A conductive base material for dye-sensitized solar cell comprising:
a first metal layer made of a metal having a specific resistance of 6×10⁻⁶ Ω·m or less; and
a second metal layer formed on the first metal layer, made of any one of metals of Ti, Cr, Ni, Mo, Ta, W, Nb, and Pt, and having a thickness of 500 nm or less.

2. The conductive base material for dye-sensitized solar cell according to claim 1, wherein the first metal layer is made of Al or stainless steel and the second metal layer is made of Cr.

3. A transparent conductive base material for dye-sensitized solar cell, comprising:
a transparent base material;
a transparent electrode layer formed on the transparent base material;
an auxiliary metal layer that has: a mesh metal layer formed in a mesh on the transparent electrode layer and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less.

4. The transparent conductive base material for dye-sensitized solar cell according to claim 3, wherein the mesh metal layer is made of Al or stainless steel.

5. The transparent conductive base material for dye-sensitized solar cell according to claim 4, wherein the second metal layer is made of Cr.

6. The transparent conductive base material for dye-sensitized solar cell according to claim 4, wherein the second metal layer is made of Ti.

7. A dye-sensitized solar cell comprising:
an oxide semiconductor electrode substrate that has: a first electrode base material functioning as an electrode, and a porous layer formed on the first electrode base material and containing a dye-sensitizer-supported fine particle of a metal oxide semiconductor;
a counter electrode substrate that has at least a second electrode base material functioning as an electrode; and
an electrolyte layer that contains a redox pair and is provided between the oxide semiconductor electrode substrate and the counter electrode substrate arranged so that the porous layer and the second electrode base material are opposed to each other,
wherein one of the first electrode base material and the second electrode base material has, as an electrode layer, a conductive base material for dye-sensitized solar cell that comprises a first metal layer made of a metal having a specific resistance of 6×10⁻⁶Ω·m or less and a second metal layer formed on the first metal layer, made of any one of metals of Ti, Cr, Ni, Mo, Ta, W, Nb, and Pt, and having a thickness of 500 nm or less; and
another is a base material having transparency.

8. The dye-sensitized solar cell according to claim 7, wherein the first metal layer of the conductive base material for dye-sensitized solar cell is made of Al or stainless steel and the second metal layer is made of Cr.

9. The dye-sensitized solar cell according to claim 7, wherein the first electrode base material has the conductive base material for dye-sensitized solar cell as the electrode layer and the second electrode base material is the base material having transparency.

10. A dye-sensitized solar cell comprising:
an oxide semiconductor electrode substrate that has: a first electrode base material functioning as an electrode and a porous layer formed on the first electrode base material and containing a dye-sensitizer-supported fine particle of a metal oxide semiconductor;
a counter electrode substrate that has at least a second electrode base material functioning as an electrode; and
an electrolyte layer that contains a redox pair and is provided between the oxide semiconductor electrode substrate and the counter electrode substrate arranged so that the porous layer and the second electrode base material are opposed to each other,
wherein at least one of the first electrode base material and the second electrode base material is a transparent conductive base material for dye-sensitized solar cell that comprises a transparent base material, a transparent electrode layer formed on the transparent base material, and an auxiliary metal layer that has a mesh metal layer formed in a mesh on the transparent electrode layer and made of a metal having a specific resistance of 6×10⁻⁶ Ω·m or less, and a second metal layer formed on the mesh metal layer, made of any one of metals of Ti, Cr, Ni, Mo, Ta, W, Nb, and Pt, and having a thickness of 500 nm or less.

11. The dye-sensitized solar cell according to claim 10, wherein the mesh metal layer of the transparent conductive base material for dye-sensitized solar cell is made of Al or stainless steel.

12. The dye-sensitized solar cell according to claim 11, wherein the second metal layer of the transparent conductive base material for dye-sensitized solar cell is made of Cr.

13. The dye-sensitized solar cell according to claim 11, wherein the second metal layer of the transparent conductive base material for dye-sensitized solar cell is made of Ti.

14. The dye-sensitized solar cell according to claim 10, wherein the first electrode base material is the transparent conductive base material for dye-sensitized solar cell.

15. A dye-sensitized solar cell module comprising two or more interconnected dye-sensitized solar cells, wherein each of the dye-sensitized solar cells comprises:
an oxide semiconductor electrode substrate that has a first electrode base material functioning as an electrode and a porous layer formed on the first electrode base material and containing a dye-sensitizer-supported fine particle of a metal oxide semiconductor;
a counter electrode substrate that has at least a second electrode base material functioning as an electrode; and
an electrolyte layer that contains a redox pair and is provided between the oxide semiconductor electrode substrate and the counter electrode substrate arranged so that the porous layer and the second electrode base material are opposed to each other, and
wherein one of the first electrode base material and the second electrode base material has, as an electrode layer, a conductive base material for dye-sensitized solar cell that comprises a first metal layer made of a metal having a specific resistance of 6×10⁻⁶ Ω·m or less and a second metal layer formed on the first metal layer, made of any one of metals of Ti, Cr, Ni, Mo, Ta, W, Nb, and Pt, and having a thickness of 500 nm or less; and another is a base material having transparency.

16. The dye-sensitized solar cell module according to claim 15, wherein the first metal layer of the conductive base material for dye-sensitized solar cell is made of Al or stainless steel, and the second metal layer is made of Cr.

17. A dye-sensitized solar cell module comprising two or more interconnected dye-sensitized solar cells, wherein each of the dye-sensitized solar cells comprises:
an oxide semiconductor electrode substrate that has a first electrode base material functioning as an electrode and a porous layer formed on the first electrode base material and containing a dye-sensitizer-supported fine particle of a metal oxide semiconductor;
a counter electrode substrate that has at least a second electrode base material functioning as an electrode; and
an electrolyte layer that contains a redox pair and is provided between the oxide semiconductor electrode substrate and the counter electrode substrate arranged so that the porous layer and the second electrode base material are opposed to each other, and
wherein at least one of the first electrode base material and the second electrode base material is a transparent conductive base material for dye-sensitized solar cell that comprises a transparent base material, a transparent electrode layer formed on the transparent base material, and an auxiliary metal layer that has a mesh metal layer formed in a mesh on the transparent electrode layer and made of a metal having a specific resistance of 6×10⁻⁶ Ω·m or less and a second metal layer formed on the mesh metal layer, made of any one of metals of Ti, Cr, Ni, Mo, Ta, W, Nb, and Pt, and having a thickness of 500 nm or less.

18. The dye-sensitized solar cell module according to claim 17, wherein the mesh metal layer of the transparent conductive base material for dye-sensitized solar cell is made of Al or stainless steel.

19. The dye-sensitized solar cell module according to claim 18, wherein the second metal layer of the transparent conductive base material for dye-sensitized solar cell is made of Cr.

20. The dye-sensitized solar cell module according to claim 18, wherein the second metal layer of the transparent conductive base material for dye-sensitized solar cell is made of Ti.
